(19) United States
(12) Patent Application Publication
(10) Pub. No.: US 2005/0082677 A1
(43) Pub. Date: Apr. 21, 2005

(54) Interconnect structure for integrated circuits

(76) Inventors: Su-Chen Fan, Chung-Li City (TW); Ding-Da Hu, Taichung City (TW)

Correspondence Address: SLATER & MATSIL, L.L.P., 17950 PRESTON ROAD, SUITE 1000, DALLAS, TX, 75252, US

(21) Appl. No.: 10/886,421

(22) Filed: Jul. 7, 2004

Related U.S. Application Data
(60) Provisional application No. 60/511,592, filed on Oct. 15, 2003.

(51) Int. Cl. H01L 23/053

(52) U.S. Cl. 257/774

(57) ABSTRACT

Interconnect structures moderate or eliminate the formation and/or migration of voids in or near via-conductive layer interfaces.

This application claims priority to provisional patent application Ser. No. 60/511,592, filed on Oct. 15, 2003, and entitled “Interconnect Structure for Integrated Circuits,” which application is incorporated herein by reference.

### TECHNICAL FIELD

The present invention relates to an interconnect structure for integrated circuits. More particularly, the present invention relates to a structure for interconnecting conductive metal layers, such as lines or pads, at different levels of an integrated circuit and conductive vias, or plugs, formed through intervening insulative or dielectric layers, the structure decreasing or eliminating voids that may form in or adjacent to the via-metal layer interfaces.

### BACKGROUND

In a typical multi-level integrated circuit (“IC”), conductive layers—which may be relatively wide elongated conductive lines, relatively wide conductive pads, or relatively wide conductive regions or strips around the periphery of the IC—reside in trenches formed in insulative layers—often called inter-metal dielectrics, or IMDs—at different levels of the IC. The conductive layers at adjacent levels are interconnected by conductive vias formed in holes extending through the IMD that intervenes between two adjacent levels of conductive layers. In a typical IC, the conductive layers and the vias are usually composed of a metal, such as copper.

In an IC, the via holes and the trenches are first formed in a higher level IMD so that one end of each hole intersects the bottom of an associated trench and the other end intersects a conductive layer on an immediately lower IMD (or on the lowermost or substrate level of the IC). Then, a conductive material, typically a metal like copper, is deposited to fill the via holes and to overfill the trenches so that the conductive vias and conductive layers are contiguous at the via hole-trench intersection. The overfill is then subjected to a removal procedure, such as chemical-mechanical polishing, which renders the conductive layers coplanar with the free surface of the upper IMD. The same procedure would have previously been followed to form the conductive layers on the lower IMD.

Dimensionally small ICs that include metal layers and metal vias fabricated according to the foregoing have exhibited defects evidenced by high or infinite electrical resistance in or near their vias, even when the vias appeared to have been correctly imaged and formed. Indeed, such via defects often appear during accelerated life testing in circuits that have previously shown neither initial defects nor infant mortality.

Studies have concluded that the root cause of some defects in metal vias results from the formation of small voids in the metal of the vias. The initial voids appear to be inherently caused by the movement and accumulation of vacancies originally randomly distributed in the metal. These vacancies are actually the empty volumes between the boundaries of neighboring metal grains. After initial formation of voids, some voids can merge with other voids and/or tend to migrate to regions where the metal vias connect to metal layers. The merged and/or migrated voids result in high via resistance, an open via, high via-layer interface resistance, or an open at such interface. “Thermal stress migration” and “electromigration” are the common terms for describing the above and related phenomena that result from various driving forces, such as thermal stress or electrical flow.

Thermal stress migration appears to be related to the different coefficients of thermal expansion of metal and the IMD. Due to this difference in thermal expansion, after metal vias and metal layers are formed, the interface between the metal and the IMDs tends to experience compressive stress, while the interface surface between two metal masses, such as the interface between a metal via and a metal layer, tends to experience tensile stress. Since the opposed stresses act at the corners where metal vias contact metal layers, small voids are easily attracted thereto, and they accumulate and merge to form larger voids, which cause poor metal via-layer interface properties, such as high or infinite electrical resistance. In IC testing procedures, cyclic heating and cooling accelerates the foregoing void migration phenomena mentioned above, and samples with poor or unacceptable electrical resistance are detected.

Electromigration (“EM”) is a result of electrical flow through metal vias and their contiguous metal layers. Specifically, at the high current densities existing in the small metal layers and vias of typical ICs, there is a significant transfer of momentum to the metal atoms from the electrons that compose the electric current. The metal atoms move and diffuse along grain boundaries and between the metal grains producing mechanical stress in the metal. Additionally, the severe geometric constraints of the surrounding IMD on the surrounded metal reduce the ability of the metal to relax this mechanical stress by plastic deformation. The unrelieved mechanical stress in the metal encourages the migration of metal atoms. The resulting stress migration leads to or exacerbates the aforementioned defects. Moreover, as the dimensions of ICs continue to shrink, atom diffusion and void migration will increase.

Further studies indicate that as the dimensional differentials between a metal via and a contiguous metal layer increase, so do void formation and migration. That is, if the dimensions of a via are quite small when compared to the width of a metal layer with which the via is contiguous, the incidence of void-caused defects increases. It has also been found that the point of contiguity between a metal via and a metal layer has an effect on void formation and migration. If a metal via and a metal layer intersect and are contiguous near a boundary of the metal layer, fewer voids are formed than is the case when the via intersects the metal layer more centrally.

Moreover, it has been postulated that void formation and migration is related to the movement of metal atoms from smaller metal grains or crystals to larger metal crystals or grains. Specifically, the surface energy of metal grains varies from grain to grain depending on grain size. Smaller grains have higher surface energy than larger grains. Examination of metal vias and metal layers has shown that metal grains in narrow vias are smaller than the metal grains in wider metal layers. Thus, metal atom migration tends to occur from a region of smaller metal grains in the metal vias to a region of larger metal grains in the metal layers in order to stabilize surface energies. The migration of metal atoms from the metal in the vias to the metal in. the metal layers effects void formation and migration.

In view of the foregoing, the present invention deals with the prevention or amelioration of the deleterious effects caused by void formation and migration. Void formation and migration have been detected in metals, such as copper, commonly used in dual damascene and other types of semiconductor fabrication, but may well occur in other metals and in non-metals. As a result, as used herein the terms “conductive” and “metal” as applied to the layers and vias of an IC, mean a metal such as copper, as well as any other conductive material, metal or non-metal, which exhibits void formation and migration of the type discussed above.

### SUMMARY OF THE INVENTION

The present invention is an interconnect structure that modifies the electrical and physical continuity of a conductive via and conductive layer formed above or beneath the via. This modification ameliorates or eliminates the tendency of void formation and migration to cause defects.

A conductive layer at one level of an IC has a relatively large width. A metal via, having relatively much smaller dimensions than the width of the conductive layer, is intended to be contiguous with and connected to the conductive layer. The via resides in a hole through an insulative layer on which or beneath which the conductive layer is formed.

In one embodiment of the present invention, a thin, elongated slot, having elongated side dimensions and relatively narrow end dimensions, is created in or through the conductive layer near an end thereof to define a first narrow path between one side of the slot and the end of the conductive layer. The length of the slot (i.e., of its sides) is less than the width of the conductive layer and defines two second narrow paths between the ends of the slot and the sides of the conductive layer. The conductive layer is electrically continuous with the first narrow path through the second paths. The via is contiguous with the first path near the end of the conductive layer.

In another embodiment, the via is contiguous with a first narrow conductive tab, preferably near or at the end of the tab. The first tab is electrically continuous with the conductive layer, which includes the slot. In a third embodiment, the first tab is rendered electrically continuous with the conductive layer by a second conductive tab intervening between the first tab and the conductive layer. The second tab is narrower than the conductive layer and wider than the first tab. The conductive layer may include the slot.

In a further embodiment, plural vias are contiguous with the first tab of either of the previous embodiments or with conductive areas located on the periphery of the IC.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a sectioned side view of a portion of a prior art multilevel integrated circuit;

FIGS. 2-4 are views similar to FIG. 1 illustrating the formation of deleterious voids in or associated with conductive vias of the integrated circuit of FIG. 1;

FIG. 5 is a top view of a portion of an integrated circuit depicting interconnect structures that, in accordance with embodiments of the present invention, decrease or eliminate the voids shown in FIGS. 2-4;

FIG. 6 is a top view of a portion of an integrated circuit depicting an interconnect structure that, in accordance with additional embodiments of the present invention, decreases or eliminates the voids shown in FIGS. 2-4; and

FIGS. 7 and 8 are partial top views of ICs depicting interconnect structures according to further embodiments of the present invention, which are modifications of embodiments depicted FIGS. 5 and 6.

### DETAILED DESCRIPTION OF ILLUSTRATIVE EMBODIMENTS

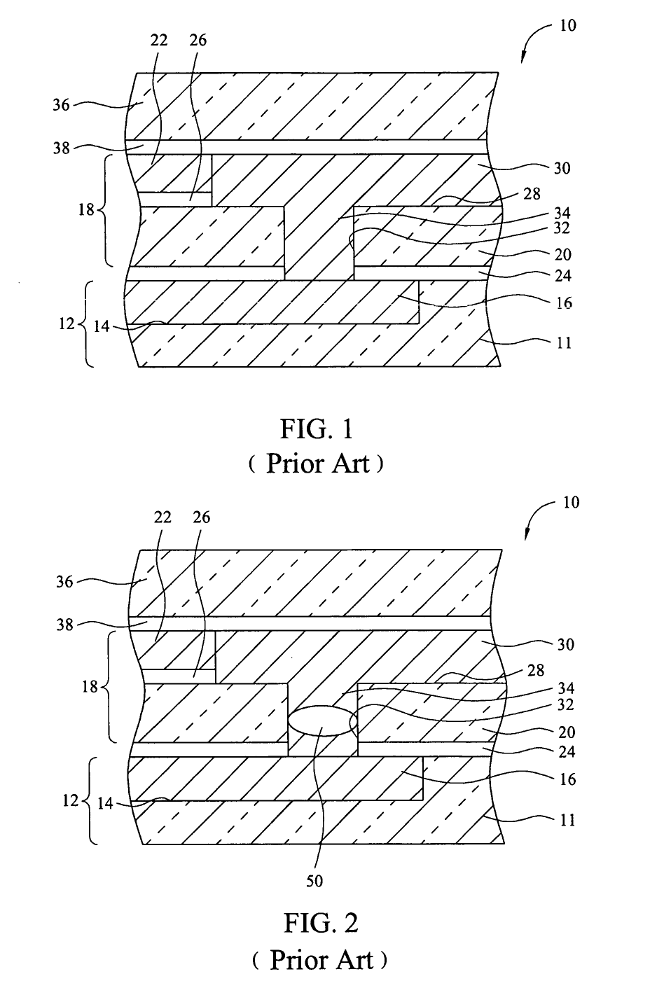

FIG. 1 shows a sectioned portion of an IC 10, which may be fabricated by dual damascene or other procedures. An IMD layer 11 forms part of a lower interconnect stack 12. A trench 14 is formed in the IMD layer 11 and is filled with a conductive layer 16 which may be a line or a pad. The conductive layer 16 has been formed by overfilling the trench 14 with a metal, such as copper, or other conductive material and then planarizing by CMP so that the top of the conductive layer 16 is coplanar with a free surface of the IMD layer 11. Another interconnect stack 18 is formed above the IMD layer 11 and the conductive layer 16. The interconnect stack 18 includes insulative, dielectric IMD layers 20 and 22 interleaved with barrier layers 24 and 26. The IMD layers 11, 20, 22 may be SiO₂, FSG (fluorine-doped silicon glass), OSG (SiOCH or organo-silicate glass), or SiC (silicon carbide), and the barrier layers 24 and 26 may be SiN, SiON, SiC, SiOC or a combination thereof.

A trench 28 is formed in the layers 22 and 26 and a conductive layer 30 is formed therein in the same manner as the conductive layer 16. A via hole 32 formed through the layers 20 and 24 is filled with a metal, such as copper, to form a via 34. In a typical dual damascene procedure, the hole 32 is formed first in alignment with a selected area of the metal layer 16 and then the trench 28 is formed so that the hole 32 intersects the bottom thereof. In other procedures, the trench 28 may be formed first to a selected depth and then the hole 32 is formed in the trench bottom. In conventional dual damascene procedures, copper is then deposited to fill the hole 32 and form a via 34 and to over-fill the trench 28. In other procedures, another metal or conductive material may be used.

A removal process, such as CMP, then renders the top of the copper or other conductive material residing above the trench 28 coplanar with the layer 22, creating the conductive layer 30.

The conductive layer 30 at the higher level of the circuit 10 is, accordingly, electrically connected to the conductive layer 16 of the lower level by the via 34. SiN and SiO₂ layers 36 and 38 may then be formed on top of the metal layer 30.

The foregoing is conventional.

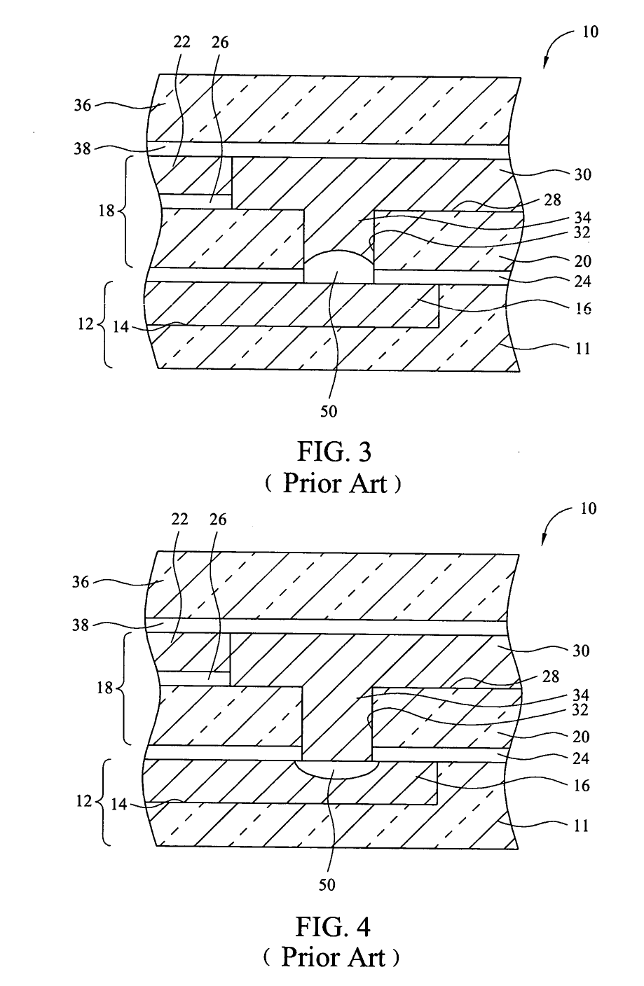

It has been found that voids 50 may form in the above-described structure 10. The defects caused by such voids 50 and the causes thereof are discussed above. In FIG. 2, a void 50 has formed in the via 34 to electrically open it. In FIG. 3, the void 50 has formed at the intended point of contiguity of the via 34 and the conductive layer 16, electrically disconnecting these elements. In FIG. 4 the void 50 has formed in the conductive layer 16 below the intended point of contiguity of the via 34 and the conductive layer 16, also disconnecting these elements. In all of these cases, electrical continuity between the conductive layers 34 and 16 is non-existent.

If the voids 50 are smaller than those depicted, infinite resistance between the conductive layer 16 and the via 34 may not result. Rather, depending on the size and location of the voids 50, the resistance of the via 34 or of the via-conductive layer 34-16 interface or intended point of contiguity may be sufficiently high to hinder proper conduction between the conductive layer 16 and 34.

The voids 50 are thought to be the result of the formation of smaller voids, which merge and migrate to the positions depicted, as described earlier regarding thermal and electromigration stresses. It is thought that unrelieved stresses of these types are responsible for or contribute to the formation of the voids 50, as discussed above.

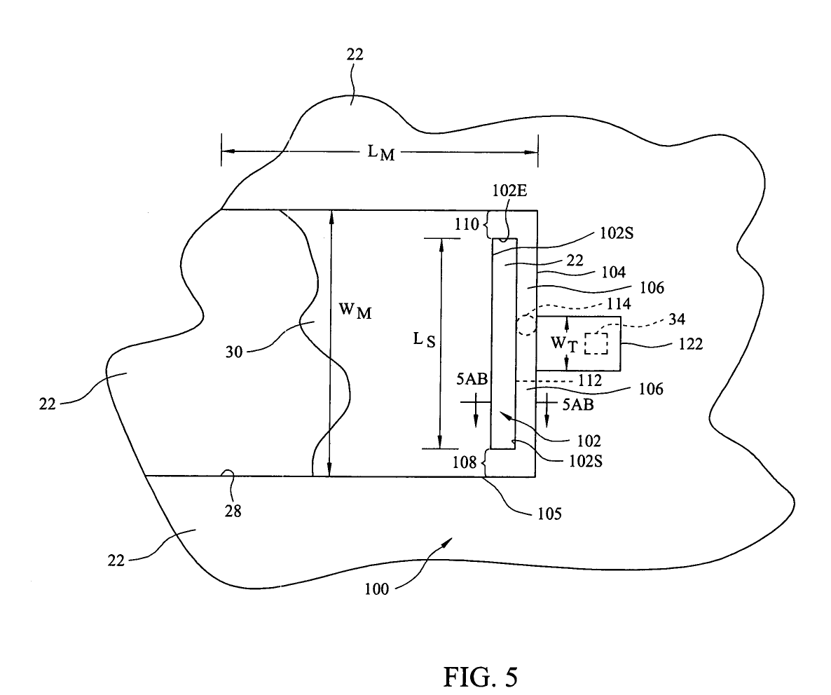

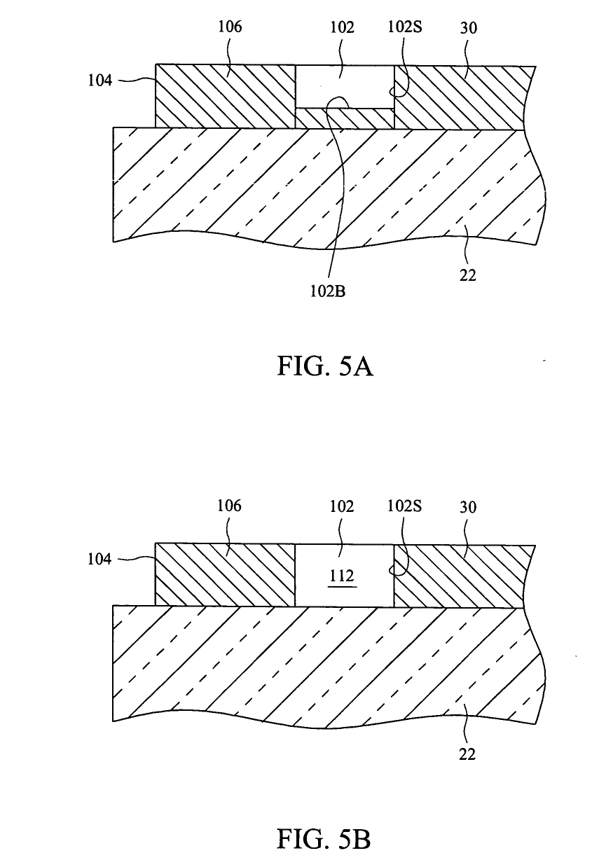

FIG. 5 depicts one embodiment of the invention and includes a view of the top surface of the conductive layer 30 residing in the trench 28 formed in the layer 22. An interconnect structure 100 according to this embodiment comprises a modification of the electrical and physical continuity of the layer 30 and the via 34, wherein an elongated slot 102 is present in the layer 30. The slot 102 has ends 102E and sides 102S. More than one slot 102 may be utilized. The slot (or slots) may be formed partially or entirely through the conductive layer 30, as shown in FIGS. 5A and 5B, respectively. The slot has ends 102E and sides 102S, and, if formed only partially through the conductive layer 30, a bottom 102B. The length L_{S}, of the slot 102 is less than the width W_{M} of the conductive layer 30.

The slot 102 is preferably, though not necessarily, formed near an end or terminus 104 of the conductive layer 30 generally centered between the sides 105 of the conductive layer 30. The slot 102 may, as shown, be generally parallel to the width W_{M} and/or the end 104 of the conductive layer 30. The slot 102 may also be non-parallel to the width W_{M} and/or the end 104. In any event, formed between the end 104 and one side 102S of the slot 102 is a narrow conductive path 106. Formed between the sides 105 of the conductive layer 30 and the ends 102E of the slot 102 are two conductive paths 108 and 110.

If the slot 102 is generally parallel to W_{M} and the end 104, the width of the first path 106—its dimension parallel to the length L_{M} of the layer 30—and the width (parallel to W_{T}) of the second paths 108 and 110 are preferably of the same order as the dimensions of the via 34. The paths 106, 108, and 110 are substantially less wide than the width of the conductive layer 30. The paths 106, 108, and 110 may have the same or slightly different widths.

The slot 102 is preferably, but not necessarily, filled with the material of the layer 22. If the slot 102 is formed entirely through the conductive layer 30, this may be achieved by leaving a body or island 112 of this material extending upwardly from the bottom of the trench 28 when the trench 28 is formed, as shown in FIG. 5B. Thereafter, over-filling the trench 28 with a conductive material—a metal such as copper or other conductive material—and planarizing results in the conductive material of the layer 30 surrounding the island 112, so that the slot 102 “contains” the material of the layer 22. The slot 102 may also be formed first in the conductive layer 30, followed by filling its volume with a suitable dielectric material. The latter technique may be utilized if the slot 102 is formed partially through the conductive layer 30, as in FIG. 5A.

The via 34 is contiguous with and extends (normally to the plane of FIG. 5) downwardly (or upwardly) from the conductive path 106 at a location generally designated 114, though another location is preferred, as set forth below. The location 114 is characterized by having dimensions of the same order as the dimensions of the via 34. The location 114 is preferably at or near the end or boundary 104 of the conductive layer. If plural slots are utilized, they are preferably generally mutually parallel and are located to the left of the slot 102 shown in FIG. 5.

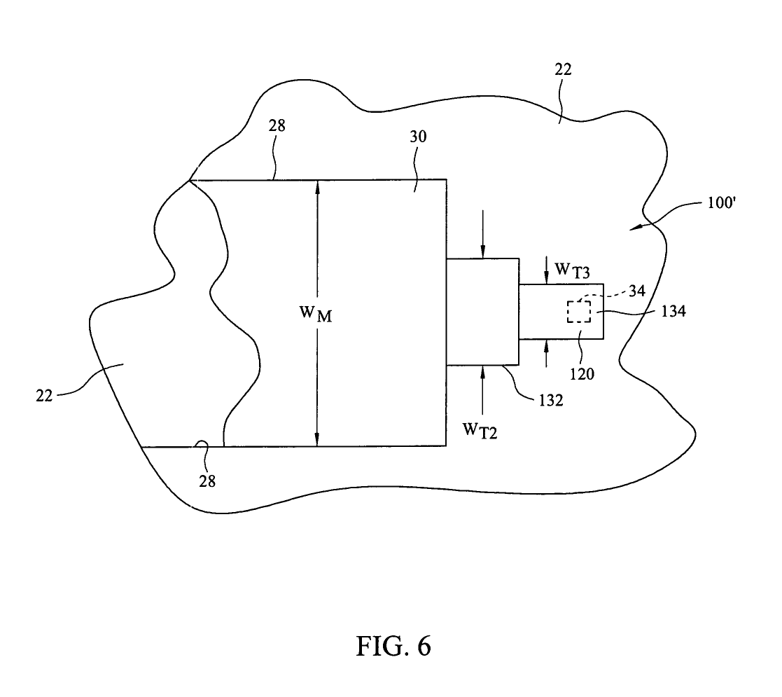

Various width dimensions W and length dimensions L of the elements of the structure are shown in or are easily derivable from FIG. 5. These length and width dimensions are in the planes of FIGS. 5-6. The subscript M designates the conductive layer 30; the subscript S designates the slot 102; and the subscript T designates a second conductive tab 132, to be described below. For convenience, the length L and the width W of the path 106 are respectively parallel to the length L_{S} and the width (not labeled) of the slot 102, where L_{S} is parallel to the width W_{M} of the conductive layer 30, and its width is parallel to the length L_{M} of the conductive layer 30. The length and width (not labeled) of the paths 108 and 110 are respectively parallel to the length L_{M} and width W_{M} of the conductive layer 30. The length and width dimensions of the via 34 are typically about the same, and are referred to herein as “dimensions” of the via 34, which, like the length L and width W dimensions in the Figures lie in the planes of FIGS. 5-6.

In a preferred form of the foregoing embodiment, a narrow conductive tab 120, which is continuous with and joins the conductive layer 30 at its end 104, is formed. The tab 120, which is preferably a continuation of the path 106, may be formed in a narrowed extension of the trench 28. The via 34 is contiguous with, and extends down (or up) from, the tab 120 at or near its end 122. The width W_{T} of the tab 120 is of the same order as the dimensions of the via 34. Thus, between the point of contiguity of the via 34 with the tab 120 and the conductive layer 30 there are interposed a number of narrow conductive paths 106, 108, 110, and 120, the location and size of which discourage or eliminate the formation and/or migration of voids.

The structure 100 may be utilized with either of conductive layers 16 or 30 (or with both of them), depending on the widths of the conductive layers 16 and 30 relative to the via 34. Specifically, it has been found expedient to utilize the structure 100 when a dimension of the conductive layer 30 is about five to about seven or more times wider than the dimensions of the via 34, or when any other larger-conductive-layer-smaller-via dimensional relationship leads to void formation and migration.

As noted earlier, void formation results from at least three conditions: (1) high size differential between a dimensionally smaller via and a dimensionally larger conductive layer; (2) locating the point of contiguity between a via and a conductive layer remote from a boundary of the metal layer; and (3) atom migration from the smaller grains present in dimensionally smaller vias to the larger grains present in dimensionally larger conductive layers.

The embodiments depicted in FIG. 5 modify the electrical and physical continuity of the layer 30 and the via 34 to reduce or eliminate voids and/or their deleterious effects. First, size differential between conductive layer 30 and via 34 is modified by the contiguity of the dimensionally small via 34 with the similarly dimensioned tab 120. The tab 120 is, in turn, continuous with the similarly dimensioned first path 106, which is itself continuous with the similarly dimensioned paths 108 and 110.

Second, the point of contiguity between the via 34 and the tab 120 (or the first path 106 if the tab 120 is not used) is located near a boundary, i.e., the end 122, of the tab 120. The same is true if the via 34 is contiguous with the path 106 at the location 114 at or near the end or boundary 104 of the conductive layer 30.

Third, the dimensional similarity of the via 34 and the tab 120, of the tab 120 and the first path 106, and of the first path 106 and the second paths 108 and 110 results in a similarity in the grain size in all thereof. This ameliorates or eliminates atom migration between the various adjacent pairs of conductive elements 108/106, 110/106, 106/120 and 120/34.

Another embodiment of the invention is shown in FIG. 6 as an interconnect structure 100′. In FIG. 6, the conductive layer 30 is rendered electrically continuous with the first narrow conductive tab 120 by a second or intermediate conductive tab 132 having a width W_{T2} intermediate the width W_{M} of the conductive layer 30 and the width W_{T1} of the second tab 120. The via 34 extends downwardly (or upwardly) from the first tab 120, preferably at or near its free end 134. The width W_{T1} of the first tab 120 is of the same order as the dimensions of the via 34, which is much smaller than the width W_{M} of the conductive layer 30. The structure 100′, may include one or more of the slots 102 described above with reference to FIGS. 5, 5A and 5B.

As with the first embodiment 100, the embodiment 100′, may be utilized with conductive layer 16 or 30 at any level of the circuit 10. Further, there may be more than one intermediate conductive tab 132 between the end 104 of the conductive layer 30 and the first tab 120, the widths of the additional intermediate tabs decreasing or tapering as the tab 120 is approached. The structure 100′ inhibits the formation and/or migration of voids by matching the width W_{T1} of the tab 120 to the dimensions of the via 34, by having the point of contiguity of the tab 120 and the via 34 near a boundary (the free end 134) of the former, and by employing one or more intermediate tabs to eliminate the large dimensional difference that would otherwise exist between the via 34 and the conductive layer 30. If one or more slots 102 are included in the structure 100′, the advantages thereof, as described previously, are also extant. The tab 120 and one or more intermediate tabs 132 may be simultaneously formed with the conductive layer 30 in appropriately formed and configured extensions of the trench 28.

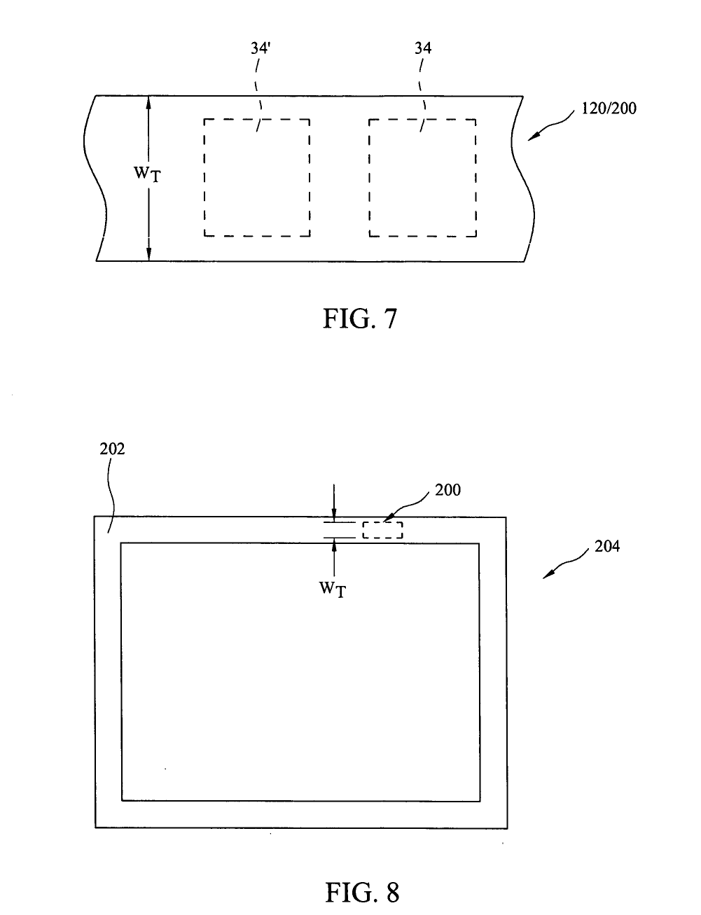

Referring now to FIGS. 7 and 8, further embodiments of the present invention are shown. In FIG. 7, a portion of the tab 120 of FIG. 5 or FIG. 6 is shown. FIG. 7 may also be viewed as showing a portion of a conductive pad 200, described in detail below. In both cases, the tab 120 and the pad 200 have the width W_{T}. Multiple vias (two are shown) 34 and 34′ are used to electrically connect the conductive tab 120 to a conductive layer above or below it. It has been found that when a via has dimensions that are smaller than about 200 nm, and more particularly smaller than about 140 nm, the possibility of void formation and migration involving or caused by the via 34 appears to increase. The use of multiple vias 34,34′ distributes the effects of factors, which might otherwise result in void formation and migration, between two or more locations, i.e., at the points of contiguity between the vias 34 and 34′ and the conductive tab 120 or the pad 200. This distribution, in combination with the location of the vias 34 and 34′ near an end or edge of the tab 120 or the pad 200 and the dimensional similarity of the width W_{T} of the tab and the pad 120 and 200 and the dimensions of the vias 34 and 34′ inhibits or eliminates void formation and migration.

As implied above, the use of the multiple vias 34 and 34′ may be extended to conductive pads or areas 200 having the width W_{T} that are located on the periphery 202 of an IC chip 204, which has numerous individual devices (not shown) formed thereon and therein. The IC chip 204 is here assumed to have dimensions of approximately 1 cm² (10⁴ μm×10⁴ μm). It should be clear that the following description applies to ICs having other dimensions. Referring to FIG. 8, the periphery 202 of the IC 204 is defined as a narrow belt or zone having a width of about W_{T}, or slightly greater, that is about 10% of the distance from the center of the IC 204 to an edge thereof, or about 1000 μm in the case of the foregoing assumed dimensions. Given that the IC 204 may be rectangular and not square, the periphery's width W may be taken as 10% of one or the other of the dimensions of the IC, or as 10% of the average of these dimensions. As indicated above, the belt or zone 202 may comprise or include numerous conductive pads or areas 200.

Each pad 200 is electrically associated with a one or more of the devices on the IC chip 204 functioning together as a specific circuit or block, such as a memory, processor, counter, voltage source or the like. The pad 200 and pad-to-via 200-to-34 connections located on or within the periphery 202 normally experience very high stress due to the accumulation of stresses arising from the fabrication of multiple devices in and on the IC chip 204 and from the multiple connections of vias 34 to conductive layers associated with the devices surrounded by the periphery 202. These high stresses lead to void formation and migration at via-pad interfaces.

The use of one or more additional vias 34′ along with the via 34 to electrically connect the pads 200 to other conductive layers has been found to decrease or eliminate void formation and migration involving such vias by modifying the electrical and physical continuity between the pad 200 and the single via 34.

Particular embodiments of the invention are described herein. It is to be understood that the invention is not limited in scope by the description and includes those modifications and equivalents covered by the following claims. Specifically, various changes, substitutions and alterations can be made herein without departing from the spirit and scope of the invention as defined by the appended claims. The scope of the present application is not intended to be limited to the particular embodiments of the structure described herein. As one of ordinary skill in the art will readily appreciate from the foregoing disclosure, structures that presently exist or are later developed and that perform substantially the same function or achieve substantially the same result as the corresponding embodiments described herein may be utilized according to the present invention. The appended claims are intended to include within their scope such structures and methods.

1. An interconnect structure for an integrated circuit, which comprises:
a conductive layer at one level of the circuit;
at least one conductive via electrically continuous with the conductive layer, the via being located in a hole through an insulative layer and extending to another level of the circuit, the width of the conductive layer between its sides being larger than the dimensions of the via; and
at least one elongated slot formed in the conductive layer proximate to the via.

2. The structure of claim 1, wherein the slot is near an end of the conductive layer.

3. The structure of claim 1, wherein the slot is filled with an insulative material.

4. The structure of claim 3, wherein the insulative material comprises low k dielectric materials.

5. The structure of claim 3, wherein the slot is formed completely through the conductive layer.

6. The structure of claim 3, wherein the slot is formed partially through the conductive layer.

7. The structure of claim 1, wherein the conductive layer and the conductive via include a metal.

8. The structure of claim 7, wherein the metal comprises copper.

9. An interconnect structure for an integrated circuit comprising:
a conductive layer at one level of the circuit;
a conductive tab having one end continuous with an end of the conductive layer;
an elongated slot formed in and near the end of the conductive layer; and
at least one conductive via located in a hole through an insulative layer and extending to another level of the circuit, the width of the conductive layer between its sides being larger than the dimensions of the via, the via being continuous with the tab near the other end thereof.

10. The structure of claim 9, wherein the conductive tab comprises at least two portions having different widths.

11. An interconnect structure for an integrated circuit comprising:
a conductive layer at one level of the circuit;
at least one conductive via electrically continuous with the conductive layer, the via being located in a hole through an insulative layer and extending to another level of the circuit, the width of the conductive layer between its sides being larger than the dimensions of the via; and
a conductive tab continuous with an end of the conductive layer, the via being contiguous with the tab at the free end thereof.

12. The structure of claim 11, wherein the conductive tab comprises at least two portions having different widths.

13. The structure of claim 12, wherein the free end of the tab is the portion thereof having the smallest width.

14. An interconnect structure for an integrated circuit comprising:
a conductive layer at one level of the circuit; and
a plurality of similarly dimensioned conductive vias electrically continuous with the conductive layer, the vias being located in respective holes through an insulative layer and extending to another level of the circuit, the width of the conductive layer between its sides being larger than the dimensions of the vias.

15. The structure of claim 14, wherein the conductive layer is a conductive pad located on a peripheral region surrounding the integrated circuit along the edges thereof.

16. The structure of claim 14, wherein the width of the peripheral region is about 10% of the distance from the center of the integrated circuit to its edge.

17. The structure of claim 16, wherein the width of the peripheral region is approximately 1000 μm.

18. The structure of claim 14, wherein the vias include a metal.

19. The structure of claim 18, wherein the metal comprises copper.

20. An interconnect structure for an integrated circuit comprising:
a conductive layer at one level of the circuit;
a first conductive via electrically continuous with the conductive layer, the via being located in a hole through an insulative layer and extending to another level of the circuit, the width of the conductive layer between its sides being larger than the dimensions of the first via; and
facilities for modifying the electrical and physical continuity of the first via and the conductive layer so that the relative sizes of the first via and the conductive layer and the location of the first via are such as to inhibit void formation and migration.

21. The structure of claim 20, wherein the modifying facilities comprise:
an elongated slot formed in, and near an end of, the conductive layer, the slot having a length less than the width of the conductive layer, one side of the slot and the end of the metal layer defining therebetween a conductive path having a width between the one side of the slot and the end of the metal layer that is of the same order as the dimensions of the via, the via being contiguous with the first path.

22. The structure of claim 20, wherein the modifying facilities comprise:
an elongated slot formed in, and near an end of, the conductive layer, the slot having a length less than the width of the conductive layer, one side of the slot and the end of the metal layer defining therebetween a conductive path having a width between the one side of the slot and the end of the metal layer that is of the same order as the dimensions of the via; and
a conductive tab contiguous with the first conductive path at the end of the conductive layer and having a width that is of the same order as the dimensions of the via, the via being contiguous with the tab near the free end thereof.

23. The structure of claim 20, wherein the modifying facilities comprise:
a conductive tab continuous at one end with an end of the conductive layer and having a width at its free end that is of the same order as the dimensions of the via, the via being contiguous with the first tab near the free end, the width of the tab at its free end being smaller than the width of the tab at its one end.

24. The structure of claim 23, wherein the modifying facilities further comprise:
an elongated slot formed in, and near the end of, the conductive layer, the slot having a length less than the width between the sides of the conductive layer, one side of the slot and the end of the metal layer defining therebetween a conductive path having a width between the one side of the slot and the end of the metal layer that is of the same order as the dimensions of the via.

25. The structure of claim 20, wherein the modifying facilities comprise:
a conductive tab continuous with an end of the conductive layer, the via being contiguous with the first tab at the free end thereof, the free end of the tab having a width of the same order as the dimensions of the via; and
one or more additional vias dimensioned similarly to the first via, the additional vias being located in respective holes through the insulative layer and extending to the other level of the circuit, the additional vias being contiguous with the first tab adjacent to the first via.

26. The structure of claim 25, wherein the modifying facilities further comprise:
an elongated slot formed in, and near the end of, the conductive layer, the slot having a length less than the width between the sides of the conductive layer, one side of the slot and the end of the metal layer defining therebetween a first conductive path having a width between the one side of the slot and the end of the metal layer that is of the same order as the dimensions of the via.

27. The structure of claim 20, wherein the conductive layer is a conductive pad located on a peripheral region surrounding the integrated circuit along the edges thereof, the conductive pad having a length larger than the dimensions of the via and a width of the order of the dimensions of the via, and wherein the modifying facilities comprise:
one or more additional vias dimensioned similarly to the first via, the additional vias being located in respective holes through the insulative layer and extending to the other level of the circuit, the additional vias being contiguous with the conductive pad adjacent to the first via along the length of the conductive pad.

28. The structure of claim 27, wherein the width of the peripheral region is about 10% of the distance from the center of the integrated circuit to its edge.

29. The structure of claim 28, wherein the width of the peripheral region is approximately 1000μ.
